(19) United States
(12) Patent Application Publication
(10) Pub. No.: US 2026/0119761 A1
(43) Pub. Date: Apr. 30, 2026

(54) SIMULATION METHOD AND SIMULATION SYSTEM BASED ON MACHINE LEARNING MODEL

(71) Applicant: SAMSUNG ELECTRONICS CO., LTD., Suwon-si (KR)

(72) Inventors: Joohyung YOU, Suwon-si (KR); Changwook JEONG, Ulsan (KR); Jaemyung CHOE, Suwon-si (KR); Giyong HONG, Ulsan (KR); Younggu KIM, Suwon-si (KR)

(73) Assignees: SAMSUNG ELECTRONICS CO., LTD., Suwon-si (KR); UNIST (Ulsan National Institute of Science and Technology), Ulsan (KR)

(21) Appl. No.: 19/300,160

(22) Filed: Aug. 14, 2025

(30) Foreign Application Priority Data
Oct. 25, 2024 (KR) 10-2024-0147934
Feb. 14, 2025 (KR) 10-2025-0019632

(51) Int. Cl. G06F 30/30

(52) U.S. Cl. CPC G06F 30/30

(57) ABSTRACT

A method of performing a device simulation of a resistive memory element includes obtaining oxide layer thickness data and input voltage data of the resistive memory element; generating predicted current data and predicted variance data for current based on a machine learning model, where the generating the predicted current data and the predicted variance data includes predicting a current corresponding to an input voltage; generating model variance data associated with a difference between a real current and the predicted current, based on the machine learning model; and performing a circuit simulation based on the machine learning model, the predicted variance data, and the model variance data.

### CROSS-REFERENCE TO RELATED APPLICATION

This application is based on and claims priority under 35 U.S.C. § 119 to Korean Patent Applications Nos. 10-2024-0147934 and 10-2025-0019632, respectively filed on Oct. 25, 2024 and Feb. 14, 2025, in the Korean Intellectual Property Office, the disclosures of which are incorporated by reference herein in their entireties.

### BACKGROUND

The present disclosure relates to a simulation method and simulation system based on a machine learning model, and more particularly, to a simulation method and simulation system using a machine learning-based compact model.

In recent years, machine learning technology has rapidly been developed in various application fields, such as data analysis, prediction, optimization, and simulations. In particular, a machine learning-based model has attracted attention because they may learn the complex behavior of a specific system or phenomenon from a large-scale data set and perform efficient and precise predictions based on the learned complex behavior. The machine learning technology has high computational efficiency compared to traditional physics-based models or empirical models and may effectively model complex nonlinear systems.

A machine learning-based compact model focuses on reducing the complexity of a model and improving computational speed while maintaining a high prediction accuracy. Above all, a compact model is becoming a key tool for reducing the burden of complex simulation operations and supporting rapid decision-making in various technical fields, such as semiconductors, electromagnetism, and thermodynamics.

### SUMMARY

The present disclosure provides a simulation method and simulation system, which may improve the accuracy and efficiency of process data and device data with variability and simulations thereof by segmenting and predicting both aleatoric uncertainty and epistemic uncertainty.

According to an aspect of the present disclosure, there is provided a method of performing a device simulation of a resistive memory element. The method includes obtaining oxide layer thickness data and input voltage data of the resistive memory element; generating predicted current data and predicted variance data for a current based on a machine learning model, where the generating the predicted current data and the predicted variance data includes predicting a current corresponding to an input voltage; generating model variance data associated with a difference between a real current and the predicted current, based on the machine learning model; and performing a circuit simulation based on the machine learning model, the predicted variance data, and the model variance data.

According to another aspect of the present disclosure, there is provided a non-transitory computer-readable storage medium configured to store at least one processor and instructions such that when the instructions are executed by the at least one processor, the instructions cause the at least one processor to obtain oxide layer thickness data and input voltage data of the resistive memory element; generate predicted current data and predicted variance data for current based on a machine learning model, where the generating the predicted current data and the predicted variance data includes predicting a current corresponding to an input voltage; generate model variance data associated with a difference between a real current and the predicted current, based on the machine learning model; and perform a circuit simulation based on the machine learning model, the predicted variance data, and the model variance data.

According to another aspect of the present disclosure, there is provided a computing system including a processor. The processor is configured to obtain oxide layer thickness data and input voltage data of the resistive memory element; generate predicted current data and predicted variance data for current based on a machine learning model, where the generating the predicted current data and the predicted variance data includes predicting a current corresponding to an input voltage; generate model variance data associated with a difference between a real current and the predicted current, based on the machine learning model; and perform a circuit simulation based on the machine learning model, the predicted variance data, and the model variance data.

### BRIEF DESCRIPTION OF DRAWINGS

Embodiments will be more clearly understood from the following detailed description taken in conjunction with the accompanying drawings in which:

FIG. 1 is a block diagram of a computing system according to an embodiment;

FIG. 2 is a diagram of an example resistive memory element, which is a prediction target of a machine learning model of FIG. 1;

FIGS. 3A, 3B, and 3C are diagrams illustrating a process of forming a conductive filament of resistive random access memory (ReRAM or RRAM);

FIG. 4A is a graph of current relative to voltage of ideal ReRAM;

FIG. 4B is a graph of current relative to voltage of real ReRAM;

FIG. 5 is a diagram of a sub-machine learning model (or a sub-ML model) according to an embodiment;

FIG. 6 is a diagram showing an example of the data flow of a sub-ML model according to an embodiment;

FIG. 7 is a diagram showing an example of a machine learning model of FIG. 1, according to an embodiment;

FIG. 8 is a block diagram of a computing system according to an embodiment;

FIG. 9 is a diagram of an example a knowledge distillation (KD) method of the computing system of FIG. 8;

FIG. 10 is a flowchart of an example of an operation of a computing system according to an embodiment;

FIGS. 11A and 11B are graphs showing a predicted current corresponding to an input voltage of a machine learning model according to a comparative example;

FIGS. 11C and 11D are graphs showing a predicted current corresponding to an input voltage of a machine learning model according to an embodiment;

FIG. 12 is a block diagram of a computer system according to an embodiment; and

FIG. 13 is a block diagram of a system according to an embodiment.

### DETAILED DESCRIPTION

To begin with, “each of modules” described herein may correspond to hardware, software, or a combination thereof, which is included in a computing system. The hardware may include at least one of a programmable component (e.g., a central processing unit (CPU), a digital signal processor (DSP), and a graphics processing unit (GPU)), a reconfiguration component (e.g., a field programmable gate array (FPGA)), and a component (e.g., an intellectual property (IP) block) providing a fixed function. The software may include at least one of a series of instructions executable by the programmable component and code that may be converted by a compiler into a series of instructions, and may be stored in a non-transitory storage medium.

As described herein, “modules” may also correspond to a plurality of layers in the context of a machine learning model such that an input to a layer of the plurality of layers may be the output of a previous layer or set of layers. In embodiments, “modules” may also refer to all layers in a specific machine learning model or a sub-set of a machine learning model.

As used herein, “a machine learning model” may have any structure that may be trained. For example, the machine learning model may include an artificial neural network, a decision tree, a support vector machine, a Bayesian network, and/or a genetic algorithm. Hereinafter, the machine learning model will be described mainly based on the artificial neural network, but embodiments are not limited thereto. The artificial neural network may include, but is not limited thereto, a convolution neural network (CNN), region with convolution neural network (R-CNN), a region proposal network (RPN), a recurrent neural network (RNN), a stacking-based deep neural network (S-DNN), a state-space dynamic neural network (S-SDNN), a deconvolution network, deep belief network (DBN), a restricted Boltzmann machine (RBM), a fully convolutional network, a long short-term memory (LSTM) network, a classification network, and a transformer based network. As used herein, the machine learning model may also be simply referred to as a model.

Also, the machine learning model may be referred to as a processing module. As used herein, the processing module may include the machine learning model or refer to a data processing unit that operates based on the machine learning model. For example, the processing module may process given input data by using an analysis, learning, or prediction process, and the machine learning model described above may be used to process the input data.

Hereinafter, various embodiments are described with reference to the accompanying drawings.

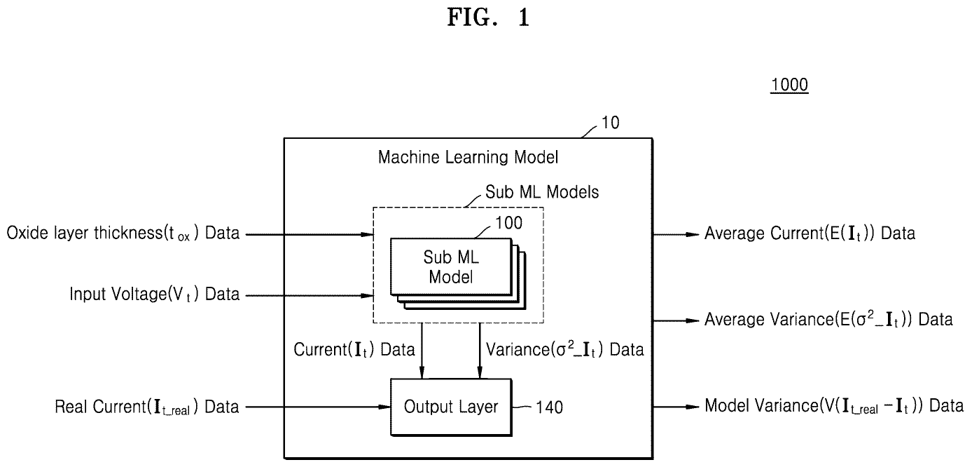

FIG. 1 is a block diagram of a computing system 1000 according to an embodiment.

A method of performing a device simulation by using a machine learning model 10 is described with reference to FIG. 1. However, the properties of a semiconductor device formed using a semiconductor process will be described as examples, but embodiments are not limited thereto. Also, embodiments may also be applied to a process simulation without being limited to the device simulation.

The computing system 1000 of FIG. 1 may include the machine learning model 10. In some embodiments, the method of performing the device simulation by using the machine learning model 10 may be performed by the computing system 1000 of FIG. 1. For example, the computing system 1000 of FIG. 1 may include at least one module implemented as hardware, software, or a combination of hardware and software, and the computing system 1000 may perform the device simulation by implementing the machine learning model 10 by using the at least one module.

The machine learning model 10 may obtain oxide layer thickness (tₒₓ) data and input voltage (Vₜ) data (may also be referred to as “target voltage (Vₜ) data). The machine learning model 10 may predict a current Iₜ corresponding to the input voltage Vₜ, based on an oxide layer thickness tₒₓ data, and generate predicted current (Iₜ) data.

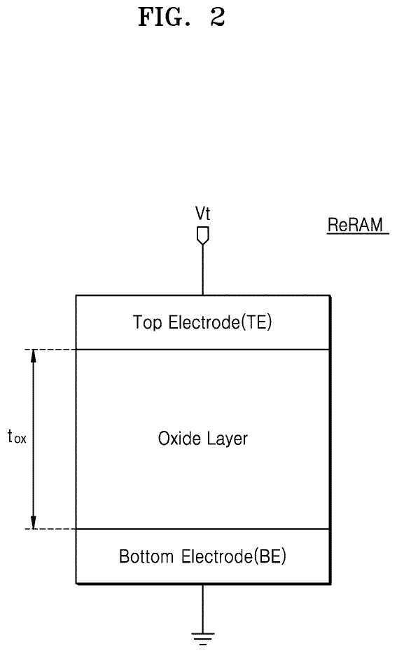

Here, the oxide layer thickness (tₒₓ) data may indicate an oxide layer thickness tₒₓ data of a resistive memory element, e.g., as resistive elements in FIGS. 2 to 4. The input voltage (Vₜ) data may indicate a voltage level applied to the resistive memory element that will be described with reference to FIGS. 2 to 4. Current (Iₜ) data may indicate a value of current Iₜ flowing through the resistive memory element, which will be described with reference to FIGS. 2 to 4, to correspond to an oxide layer thickness tₒₓ data and an input voltage Vₜ.

Also, the machine learning model 10 may predict the current Iₜ corresponding to the input voltage Vₜ and a variance (σ²_Iₜ) for current, based on the oxide layer thickness tₒₓ data, and generate the predicted current (Iₜ) data and the predicted variance (σ²_Iₜ) data for current.

Here, the predicted variance (σ²_Iₜ) data for current may indicate current characteristics (i.e., variability in randomness for data) of the resistive memory element, which will be described with reference to FIGS. 2 to 4, and may be referred to as a value of aleatoric uncertainty. That is, the aleatoric uncertainty may occur due to intrinsic randomness of data and may be essential uncertainty of data.

Also, the machine learning model 10 may additionally obtain real current (I_{t_real}) data. The machine learning model 10 may generate model variance (V(I_{t_real}-Iₜ)) data about a difference between a real current I_{t_real} and a predicted current Iₜ, based on the real current (I_{t_real}) data and the predicted current (Iₜ) data.

Here, the real current (I_{t_real}) data may indicate a value of the real current I_{t_real} that is experimentally measured by the resistive memory element, which will be described with reference to FIGS. 2 to 4, in response to an input voltage. Also, the model variance (V(I_{t_real}-Iₜ)) data about the difference between the real current I_{t_real} and the predicted current Iₜ, which is a numerical representation of the reliability of the machine learning model 10, may be referred to as a value of epistemic uncertainty. That is, epistemic uncertainty may be uncertainty that occurs due to a lack of training data, limitations in a model structure, etc.

According to the present disclosure, the accuracy and efficiency of the device simulation may be improved by segmenting and predicting both aleatoric uncertainty and epistemic uncertainty by using the machine learning model 10.

Specifically, the aleatoric uncertainty may be derived from intrinsic variability (e.g., measurement errors, environmental changes, etc.) in data. The machine learning model 10 according to the present disclosure may accurately reflect the variability in the data by separating and explicitly predicting the aleatoric uncertainty. As a result, the reliability of predicted values may be analyzed precisely based on the simulation results.

The epistemic uncertainty may be uncertainty that occurs when a model cannot be sufficiently generalized from training data. By separating and explicitly predicting the epistemic uncertainty by using the machine learning model 10 according to the present disclosure, the computing system 1000 may clearly identify the limitations of the machine learning model 10 (e.g., lack of data, biased learning, etc.). As a result, the machine learning model 10 may be improved or an area where additional training data is needed may be identified.

By simultaneously predicting the aleatoric uncertainty and the epistemic uncertainty, one machine learning model 10 according to the present disclosure may consider the uncertainty of data and models together without additional calculations. As a result, redundant computations may be reduced during a simulation operation, resource consumption may be minimized, and overall efficiency may be improved.

When the aleatoric uncertainty and/or the epistemic uncertainty are not predicted, it may be difficult to know whether model results are incorrect predictions or due to natural variability in data. The machine learning model 10 according to the present disclosure may quantitatively evaluate the reliability of each result by predicting two uncertainties separately. Thus, the analysis of results may be made clearer, and the quality of decision-making may be improved during a design optimization process. A semiconductor device (e.g., resistive random access memory (ReRAM or RRAM)) may be significantly affected by physical characteristics and data variability. By comprehensively considering the data variability and the reliability of the machine learning model 10 according to the present disclosure, the results of a process simulation, a device simulation, and/or a simulation program with integrated circuit emphasis (SPICE) may effectively reflect reality and increase the accuracy of design optimization.

Referring to FIG. 1, the machine learning model 10 may include a plurality of sub-machine learning models (or sub-ML models) 100 and an output layer 140.

Each of the plurality of sub-ML models 100 may obtain oxide layer thickness (tₒₓ) data and input voltage (Vₜ) data.

Each of the plurality of sub-ML models 100 may predict current Iₜ data corresponding to the input voltage Vₜ and a variance (σ²_Iₜ) data for current, based on an oxide layer thickness tₒₓ data, and thus, the machine learning model 10 may generate the predicted current (Iₜ) data and the predicted variance (σ²_Iₜ) data for current.

The output layer 140 may obtain, from the plurality of sub-ML models 100, the predicted current (Iₜ) data and the predicted variance (σ²_Iₜ) data for current and output average current (E(Iₜ)) data and average variance (E(σ²_Iₜ)) data.

Herein, the average current (E(Iₜ)) data may indicate an average value of predicted currents Iₜ obtained from the plurality of sub-ML models 100. Also, the average variance (E(σ²_Iₜ)) data may indicate an average value of predicted variances (σ²_Iₜ) for currents, which are obtained from the plurality of sub-ML models 100.

That is, the output layer 140 may calculate the average value of the predicted currents Iₜ obtained from the plurality of sub-ML models 100 and output the average current (E(Iₜ)) data. Also, the output layer 140 may calculate the average value of the predicted variances (σ²_Iₜ) for currents, which are obtained from the plurality of sub-ML models 100, and output the average variance E(σ²_Iₜ)) data.

In addition, the output layer 140 may obtain real current (I_{t_real}) data. The output layer 140 may generate model variance V(I_{t_real}-Iₜ)) data about differences between a real current I_{t_real} and the predicted currents Iₜ, based on the real current (I_{t_real}) data and the predicted current (Iₜ) data obtained from the plurality of sub-ML models 100.

That is, the output layer 140 may output the model variance V(I_{t_real}-Iₜ)) data by calculating a variance for a difference between the real current I_{t_real} and each of predicted currents Iₜ, which are obtained from the plurality of sub-ML models 100.

In other words, the average variance E(σ²_Iₜ)) data may be a value that aggregates the uncertainty of intrinsic characteristics that occur in a resistive memory element, which is a prediction target. A model variance V(I_{t_real}-Iₜ) may be a numerical value of the uncertainty of the machine learning model 10, based on errors between predicted values obtained by the plurality of sub-ML models 100 and real values.

According to the present disclosure, the accuracy and efficiency of the device simulation may be improved by segmenting and predicting both aleatoric uncertainty and epistemic uncertainty by using the machine learning model 10.

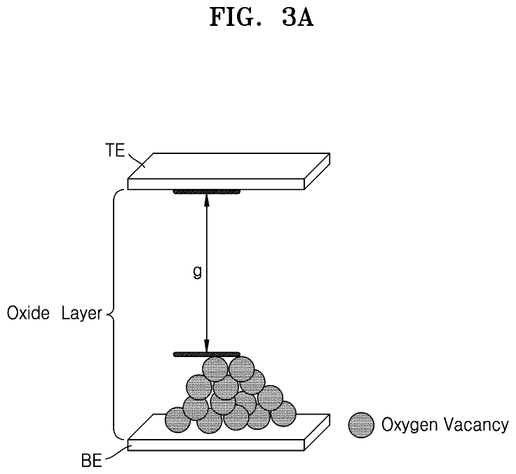

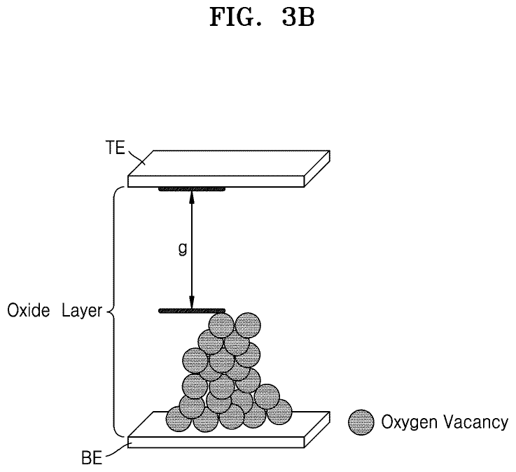

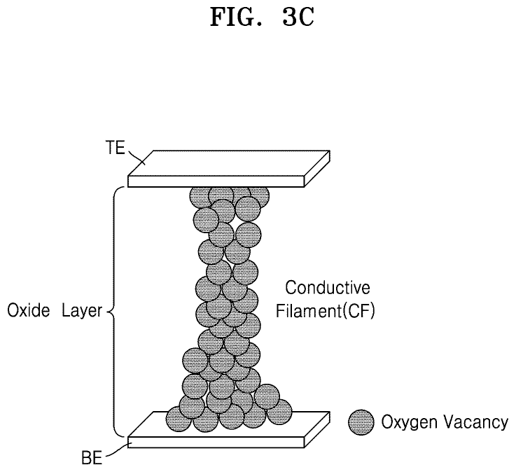

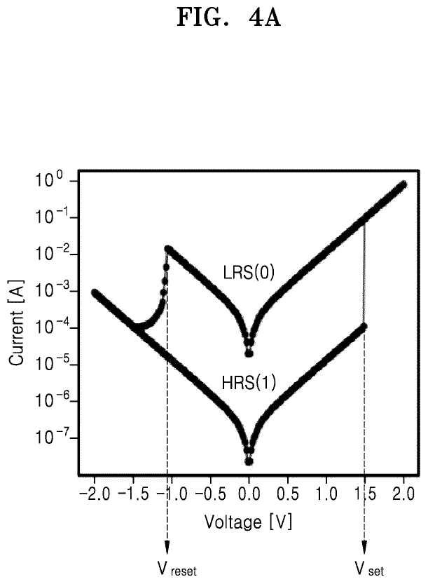

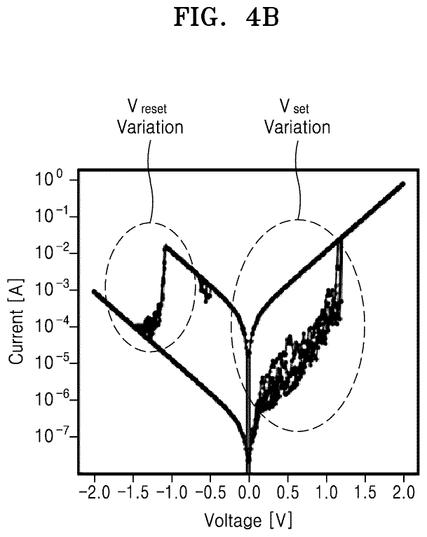

FIG. 2 is a diagram of an example of a resistive memory element, which is a prediction target of a machine learning model of FIG. 1. FIGS. 3A, 3B, and 3C are diagrams illustrating a process of forming a conductive filament of ReRAM. FIG. 4A is a graph of current relative to voltage of ideal ReRAM, and FIG. 4B is a graph of current relative to voltage of real ReRAM.

FIG. 2 is a schematic diagram of ReRAM, which is an example of the resistive memory element.

However, the present disclosure is not limited thereto, and may also be applied to any memory device having at least two different states (e.g., logical states or resistance states) (or hysteresis characteristics) for one voltage. For instance, the present disclosure may be applied to magnetoresistive RAM (MRAM) and phase-change RAM (PCRAM) having switching hysteresis or resistance variation hysteresis.

Although the ReRAM is mainly described as a prediction target of the machine learning model 10, embodiments are not limited thereto.

Referring to FIG. 2, the ReRAM may include a top electrode TE, an oxide layer, and a bottom electrode BE. That is, the ReRAM may have a metal/insulator/metal (MIM) structure. Herein, the insulator may include a metal oxide and be hereinafter referred to as an oxide layer. Also, an oxide layer thickness tₒₓ refers to a thickness of the oxide layer formed between the top electrode TE and the bottom electrode BE.

The ReRAM may be a memory device of which a resistance variably changes by generating or rupturing a conductive filament CF inside the oxide layer with the application of a voltage to the top electrode TE and/or the bottom electrode BE. For instance, referring to FIG. 2, the top electrode TE may be connected to an input voltage (Vₜ) line, and the bottom electrode BE may be connected to a ground voltage line. Hereinafter, an input voltage Vₜ may refer to a voltage applied to the ReRAM or an applied voltage.

Operations of the ReRAM may be divided into a forming operation, a reset mode operation, and a set mode operation. The forming operation may mean initially generating a conductive filament, which allows current to flow in the oxide layer, by applying a high voltage to both ends (the top electrode TE and/or the bottom electrode BE) of the oxide layer. The reset mode operation may mean forming a high resistance state HRS by rupturing the conductive filament with the application of a reverse voltage or a low voltage to the both ends (the top electrode TE and/or the bottom electrode BE) of the oxide layer. The set mode operation may mean forming a low resistance state LRS by regenerating or maintaining the conductive filament with the application of a forward voltage or an appropriately high voltage to the both ends (the top electrode TE and/or the bottom electrode BE) of the oxide layer.

Referring to FIGS. 3A to 3C, by applying a forward voltage or the appropriately high voltage to the both ends (the top electrode TE and/or the bottom electrode BE) of the oxide layer, it can be seen that a conductive filament CF is formed between the top electrode TE and the bottom electrode BE in the order of FIGS. 3A to 3C (the forming operation or the set mode operation). Also, by applying the reverse voltage or the low voltage to the both ends (the top electrode TE and/or the bottom electrode BE) of the oxide layer, the conductive filament CF ruptures between the top electrode TE and the bottom electrode BE, viewed in the order of FIGS. 3C to 3A (the reset mode operation).

Referring to FIGS. 3A to 3C, a conductive filament CF may be formed due to oxygen vacancy, which is a vacancy created when oxygen ions escape from an oxide, the migration of the escaped oxygen ions, and recombination of the oxygen ions and the oxygen vacancy.

Referring to FIGS. 3A to 3C, electron tunneling conduction of ReRAM may vary depending on an average tunneling gap distance g. The average tunneling gap distance g may be an important factor in controlling a resistance of the ReRAM. Here, the average tunneling gap distance g may indicate an average distance from an end of the conductive filament CF to the top electrode TE.

Also, conductance and current of the ReRAM may be closely related to the geometric evolution of the conductive filament CF, which may depend on the history of an applied voltage.

For instance, in order for the ReRAM to operate in a set mode (or perform the forming operation), a voltage (or the input voltage Vₜ) having a set voltage (Vₛₑₜ) level or higher may be applied to the ReRAM, and thus, oxygen vacancy and oxygen ions may be generated. Oxygen ions may continuously drift toward the top electrode TE and form a conductive filament CF configured to connect the top electrode TE to the bottom electrode BE. As a result, a high resistance state HRS may be switched to a low resistance state LRS. Here, a set voltage Vₛₑₜ may refer to a minimum applied voltage required for the ReRAM to switch from the high resistance state HRS to the low resistance state LRS. Referring to FIG. 4A, by applying the set voltage Vₛₑₜ to the ReRAM that is in the high resistance state HRS, the ReRAM is switched from the high resistance state HRS to the low resistance state LRS. Referring to FIG. 4A, when the ReRAM operates in the low resistance state LRS, the ReRAM may be maintained in the low resistance LRS until an applied voltage is lowered to a reset voltage Vᵣₑₛₑₜ.

Conversely, in order for the ReRAM to operate in a reset mode, a voltage (or the input voltage Vₜ) having a reset voltage (Vᵣₑₛₑₜ) level or lower may be applied to the ReRAM, and thus, the conductive filament CF due to oxygen vacancy and oxygen ions may be gradually dissolved. As a result, the low resistance state LRS may be switched to the high resistance state HRS. Here, a reset voltage Vᵣₑₛₑₜ may refer to a maximum applied voltage required for the ReRAM to switch from the low resistance state LRS to the high resistance state HRS. Referring to FIG. 4A, by applying the reset voltage Vᵣₑₛₑₜ to the ReRAM that is in the low resistance state LRS, the ReRAM may be switched from the low resistance state LRS to the high resistance state HRS. Referring to FIG. 4A, when the ReRAM operates in the high resistance state HRS, the ReRAM may be maintained in the high resistance state HRS until an applied voltage increases to a set voltage Vₛₑₜ.

That is, a set voltage Vₛₑₜ and a reset voltage Vᵣₑₛₑₜ, which are significant voltages that cause state changes in the ReRAM, may interact, and the ReRAM may be switched between the high resistance state HRS and the low resistance state LRS. When the ReRAM is in the high resistance state HRS, the ReRAM may be maintained in the high resistance state HRS until an applied voltage (or an input voltage Vₜ) is lowered to a reset voltage Vᵣₑₛₑₜ) level or lower. When the ReRAM is in the low resistance state LRS, the ReRAM may be maintained in the low resistance state LRS until the applied voltage (or the input voltage Vₜ) rises to a set voltage (Vₛₑₜ) level or higher.

Moreover, operations of the ReRAM may depend on the formation and annihilation of oxygen vacancies, which serve as migration paths of electrons in the ReRAM, and may follow a very complex and probabilistic process. Such randomness factors may cause variability in several characteristics. For instance, variability may occur in a current value for a voltage level. Referring to FIG. 4B, variability may also occur in a set voltage Vₛₑₜ and a reset voltage Vᵣₑₛₑₜ. Iₜ is very important to simulate the performance of the ReRAM by considering the variability in the characteristics due to the randomness factors.

For example, a compact model that represents characteristics of the real ReRAM may be as shown in Equation 1:

$$\begin{matrix}\frac{d g}{dt} = - {v}_{0} exp ( - \frac{{E}_{a}}{kT} sinh ( \frac{q γ {a}_{0} V}{{kt}_{ox} T} ) ) + {δ}_{g} ( T ) x ( t ) \\ γ = {γ}_{0} - β * {g}^{3} \\ T = {T}_{0} + {V IR}_{th} \\ I = {I}_{0} {e}^{- \frac{g}{{g}_{0}}} sinh ( \frac{V}{{V}_{0}} ) \\ {δ}_{g} ( T ) = \frac{{δ}_{g}^{0}}{1 + {e}^{\frac{{T}_{crit} - T}{{T}_{smth}}}}\end{matrix} \qquad Equation 1$$

wherein

$$\frac{d g}{dt}$$

denotes a variation of the average tunneling gap distance g with respect to time, v₀ denotes a formation rate constant of a conductive filament CF, Eₐ denotes activation energy, which is energy required for the formation or rupture of the conductive filament CF, k denotes a Boltzmann constant, T denotes a temperature of the oxide film, tₒₓ denotes a thickness of the oxide film, q denotes a basic charge of electrons. Further, V denotes an input voltage (Vₜ) level between the top electrode TE and the bottom electrode BE, a₀ denotes a basic unit of distance or a characteristic length, which is a physical length involved in electron migration or filament formation, γ denotes a coefficient related to the formation/rupture or tunneling of the conductive filament CF and represents a voltage sensitivity of the conductive filament CF. In Equation 1, δ_{g}(T) denotes a stochastic and temperature-dependent filament migration, and x(t) denotes a random noise signal with a mean of 0, a Gaussian distribution, and a Root mean square of unity (RMS) value of 1.

γ₀ denotes an initial voltage sensitivity when the average tunneling gap distance g is 0, and β denotes a constant defining a relationship g³ and γ. That is, γ may nonlinearly vary according to the average tunneling gap distance g.

Also, T₀ denotes an initial temperature of the oxide film, and VtRₜₕ denotes a rise in temperature caused by current and voltage. That is, T may reflect a heat generation effect that occurs during an operation of the ReRAM.

Also, I denotes current flowing through the oxide film according to the average tunneling gap distance g and the applied voltage V, I₀ denotes a current constant, g₀ denotes a reference tunneling gap distance (or an initial tunneling gap distance), and V₀ denotes a reference voltage (or an initial voltage). Thus, I may nonlinearly vary according to the average tunneling gap distance g and the applied voltage V.

$${δ}_{g}^{0}$$

denotes an initial value of randomness, T_{crit} denotes a critical temperature, which represents a temperature at which δ_{g}(T) begins to change rapidly, and Tₛₘₜₕ denotes a temperature smoothing constant, which may be used as a parameter to determine how smoothly the stochastic and temperature-dependent filament migration δ_{g}(T) changes. Thus, the stochastic and temperature-dependent filament migration δ_{g}(T)) may be used to reflect variability in characteristics of ReRAM. For example, in the variation

$$( \frac{d g}{dt} )$$

of the average tunneling gap distance g with respect to time, the stochastic and temperature-dependent filament migration (δ_{g}(T)) may reflect randomness and variability in characteristics.

As described above, the compact model according to Equation 1 may be mathematically defined based on physical principles, and may provide physical intuition and help understand the basic principles of a device. However, the compact model may only operate under specific conditions and may not accurately predict various operation conditions due to nonlinear relationships or complex randomness.

In contrast, the machine learning model 10 according to the present disclosure may predict complex operations of the ReRAM concisely by learning experimental data. That is, the computing system 1000 according to the present disclosure may train the machine learning model 10 to learn the nonlinear relationships or complex randomness described above, based on training data (e.g., experimental data or simulation data generated by the compact model according to Equation 1). The computing system 1000 according to the present disclosure may predict operations of the ReRAM quickly and accurately by using the trained machine learning model 10. Herein, the machine learning model 10 may be referred to as a machine learning-based compact model.

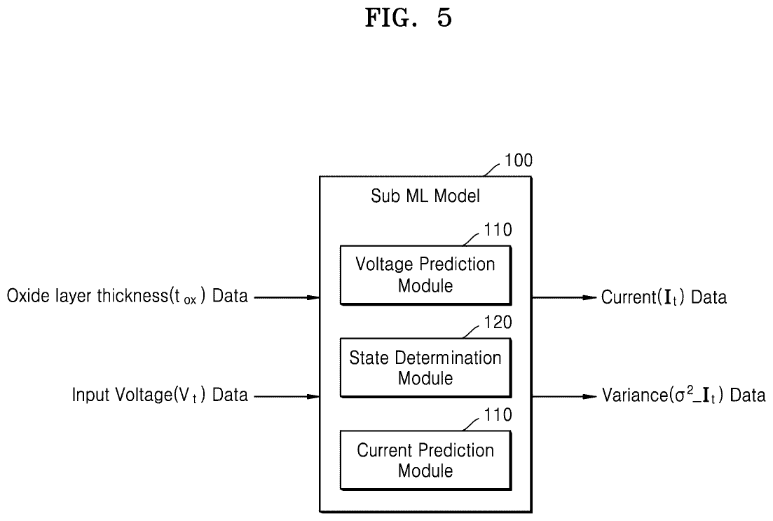

Hereinafter, a method by which the computing system 1000 trains the machine learning-based compact model or a method by which the computing system 1000 makes inferences by using the machine learning-based compact model is described in detail with reference to FIGS. 5 to 11.

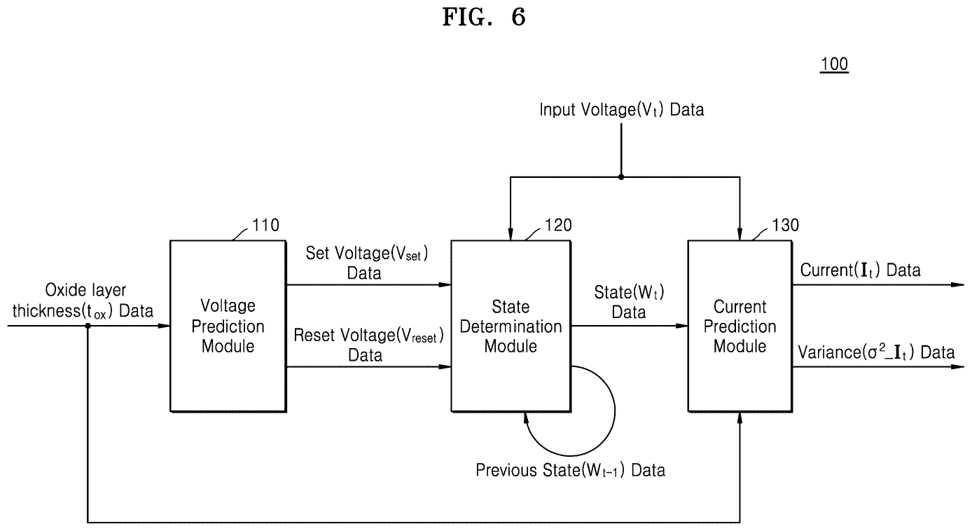

FIG. 5 is a diagram of a sub-ML model according to an embodiment. FIG. 6 is a diagram showing an example of the data flow of a sub-ML model according to an embodiment.

FIG. 5 illustrates a sub-ML model 100 corresponding to one of the plurality of sub-ML models described with reference to FIG. 1.

Herein, the sub-ML model 100 may be implemented as an artificial neural network. The artificial neural network that implements the sub-ML model 100 may be referred to as a sub-artificial neural network in an offline process, and may be referred to as a pre-trained sub-artificial neural network in an online process.

For example, the offline process may refer to a section where data or tasks are prepared or processed in advance. For example, a process of training an artificial neural network may be included in the offline process. That is, in the offline process, a computing system 1000 may train the artificial neural network based on training data (e.g., labeling data). The trained artificial neural network may be used or applied later in the online process.

For example, the online process may refer to a section where data is processed in real time or a task corresponding to a real-time situation is performed. As an example, an inference process in which the computing system 1000 performs predictions on real data by using a pre-trained artificial neural network may be included in the online process.

Referring to FIG. 5, the sub-ML model 100 may obtain oxide layer thickness (tₒₓ) data and input voltage (Vₜ) data (also referred to as target voltage (Vₜ) data). A machine learning model 10 may predict a current Iₜ corresponding to an input voltage Vₜ and a variance (σ²_Iₜ) for current, based on an oxide layer thickness tₒₓ, and thus, the sub-ML model 100 may generate predicted current (Iₜ) data and predicted variance (σ²_Iₜ) data for current.

Herein, the oxide layer thickness (tₒₓ) data may denote an oxide layer thickness tₒₓ of the resistive memory element described with reference to FIGS. 2 to 4. The input voltage (Vₜ) data may indicate a voltage level applied to the resistive memory element described with reference to FIGS. 2 to 4. Current (Iₜ) data may denote a value of current (Iₜ) flowing through the resistive memory element described with reference to FIGS. 2 to 4 to correspond to the oxide layer thickness tₒₓ and the input voltage Vₜ. The predicted variance (σ²_Iₜ) data for current may indicate variability in randomness for current in the resistive memory element described with reference to FIGS. 2 to 4, and may be referred to as a value of aleatoric uncertainty. That is, the aleatoric uncertainty may occur due to intrinsic randomness of data and may be essential uncertainty of data.

Referring to FIGS. 5 and 6, the sub-ML model 100 may include a voltage prediction module 110, a state determination module 120, and a current prediction module 130.

Iₜ must be understood that each of the voltage prediction module 110, state determination module 120, and current prediction module 130 may be implemented as one or more layers of a machine learning model, which may be the machine learning model 10, a sub-set of the machine learning model 10, or a model distinct from machine learning model 10.

Referring to FIG. 6, the voltage prediction module 110 may obtain the oxide layer thickness (tₒₓ) data. The voltage prediction module 110 may output predicted set voltage (V set) data and predicted reset voltage (Vᵣₑₛₑₜ) data, based on the oxide layer thickness (tₒₓ) data.

The voltage prediction module 110 may predict switching voltages (e.g., a set voltage Vₛₑₜ and a reset voltage Vᵣₑₛₑₜ)) corresponding to the oxide layer thickness (tₒₓ), based on the oxide layer thickness (tₒₓ) data, and generate the predicted set voltage (Vₛₑₜ) data and the predicted reset voltage Vᵣₑₛₑₜ) data.

Here, the set voltage Vₛₑₜ may refer to a minimum input voltage Vₜ required for the resistive memory element (e.g., described with reference to FIGS. 2 to 4) to be switched from the high resistance state HRS to the low resistance state LRS. The reset voltage Vᵣₑₛₑₜ may refer to a maximum input voltage Vₜ required for the resistive memory element (e.g., described with reference to FIGS. 2 to 4) to be switched from the low resistance state LRS to the high resistance state HRS.

Also, the voltage prediction module 110 may include a pre-trained artificial neural network. According to an embodiment, in the offline process, the computing system 1000 may train the voltage prediction module 110, based on first labeling data, such that the voltage prediction module 110 predicts the corresponding switching voltages (e.g., the set voltage Vₛₑₜ and the reset voltage Vᵣₑₛₑₜ), based on a given oxide layer thickness tₒₓ.

Here, the first labeling data may be a set of real switching voltages (e.g., a real set voltage V_{set_real} and a real reset voltage V_{reset_real}) corresponding to the oxide layer thickness tₒₓ. That is, the first labeling data may indicate a set of real set voltage (V_{set_real}) data according to the oxide layer thickness tₒₓ and real reset voltage (V_{reset_real}) data according to the oxide layer thickness tₒₓ.

In an embodiment, in the offline process, the computing system 1000 may train the voltage prediction module 110 to minimize the loss of the real set voltage V_{set_real} according to the oxide layer thickness tₒₓ and the set voltage Vₛₑₜ predicted by the voltage prediction module 110 according to the oxide layer thickness tₒₓ. For example, the computing system 1000 may update a parameter (e.g., a weight) included in the voltage prediction module 110 to minimize the loss of the real set voltage V_{set_real} according to the oxide layer thickness tₒₓ and the set voltage Vₛₑₜ predicted by the voltage prediction module 110 according to the oxide layer thickness tₒₓ.

In an embodiment, in the offline process, the computing system 1000 may train the voltage prediction module 110 to minimize the loss of the real reset voltage V_{reset_real} according to the oxide layer thickness tₒₓ and the reset voltage Vᵣₑₛₑₜ predicted by the voltage prediction module 110 according to the oxide layer thickness tₒₓ. For example, the computing system 1000 may update a parameter (e.g., a weight) included in the voltage prediction module 110 to minimize the loss of the real reset voltage V_{reset_real} according to the oxide layer thickness tₒₓ and the reset voltage Vᵣₑₛₑₜ predicted by the voltage prediction module 110 according to the oxide layer thickness tₒₓ.

In an embodiment, in the online process, the voltage prediction module 110 may generate set voltage (Vₛₑₜ) data and reset voltage (Vᵣₑₛₑₜ) data from the obtained oxide layer thickness (tₒₓ) data, based on pre-trained parameters. Herein, in the offline process, the pre-trained parameters may be parameters that are updated to minimize loss between the real set voltage Vₛₑₜ real and the predicted set voltage Vₛₑₜ and loss between the real reset voltage V_{reset_real} and the predicted reset voltage Vᵣₑₛₑₜ.

Referring to FIG. 6, the state determination module 120 may obtain input voltage (Vₜ) data (also referred to as target voltage (Vₜ) data), set voltage (Vₛₑₜ) data, and reset voltage (Vᵣₑₛₑₜ) data. The state determination module 120 may generate state (Wₜ) data according to the input voltage Vₜ, based on the input voltage (Vₜ) data, the set voltage (Vₛₑₜ) data, the reset voltage (Vᵣₑₛₑₜ) data, and previous state (Wₜ₋₁) data.

In an embodiment, the state determination module 120 may compare an input voltage Vₜ with the set voltage Vₛₑₜ and the reset voltage Vᵣₑₛₑₜ, and determine a previous state Wₜ₋₁ as a state Wₜ according to the input voltage Vₜ or determine a state different from the previous state Wₜ₋₁ as the state Wₜ according to the input voltage Vₜ, depending on whether specific conditions are satisfied.

For example, the specific conditions described above may be as shown in Equation 2:

$$\{ \begin{matrix}{W}_{0} = 1 ( initial ) \\ {W}_{t} = 0 ( If {V}_{t} > {V}_{set} ) \\ {W}_{t} = 1 ( If {V}_{t} < {V}_{reset} ) \\ {W}_{t} = {W}_{t - 1} ( Else )\end{matrix} \qquad Equation 2$$

wherein 0 denotes a low resistance state LRS, 1 denotes a high resistance state HRS, W₀ denotes an initial state of a resistive memory element, which may be the high resistance state HRS, Wₜ denotes a present state as the state Wₜ according to the input voltage Vₜ, and Wₜ₋₁ denotes a previous state Wₜ₋₁ according to a previous input voltage Vₜ₋₁, which indicates a previous state before the input voltage (Vₜ) is applied.

For brevity, it is now assumed that after an input voltage (Vₜ) level gradually increases and exceeds a set voltage (Vₛₑₜ) level, the input voltage (Vₜ) level is gradually reduced and becomes below a reset voltage (Vᵣₑₛₑₜ) level. However, the present disclosure is not limited thereto, and the input voltage (Vₜ) level may gradually increase, gradually decrease, or change without any particular trend.

In the resistive memory element that is in the high resistance state HRS, when the input voltage (Vₜ) level is lower than the set voltage (Vₛₑₜ) level, both the previous state Wₜ₋₁ according to the previous input voltage (Vₜ₋₁) and the state Wₜ according to the input voltage Vₜ may be 1. For example, even when the input voltage (Vₜ) level gradually increases in the resistive memory element that is in the high resistance state HRS, because the input voltage (Vₜ) level is lower than the set voltage (Vₛₑₜ) level, the resistive memory element may be maintained in the high resistance state HRS.

That is, when the previous state Wₜ₋₁ is 1 (or the high resistance state HRS) and the input voltage (Vₜ) level is lower than the set voltage (Vₛₑₜ) level, the state determination module 120 may determine the previous state Wₜ₋₁ (1) as the state Wₜ (1) according to the input voltage Vₜ.

In the resistive memory element that is in the high resistance state HRS, when an applied input voltage (Vₜ) level first becomes the set voltage (Vₛₑₜ) level or higher, the previous state Wₜ₋₁ according to the previous input voltage Vₜ₋₁ may be 1, but the state Wₜ according to the input voltage Vₜ may be determined as 0. For example, in the resistive memory element that is in the high resistance state HRS, when the input voltage (Vₜ) level gradually increases and first becomes the set voltage (Vₛₑₜ) level or higher, the resistive memory element in the high resistance state HRS may be switched to a low resistance state LRS.

That is, when the previous state Wₜ₋₁ is 1 (or the high resistance state HRS) and the input voltage (Vₜ) level is the set voltage (Vₛₑₜ) level or higher, the state determination module 120 may determine a state (0) different from the previous state Wₜ₋₁ (1) as the state Wₜ according to the input voltage Vₜ.

In the resistive memory element that is in the low resistance state LRS, when the input voltage (Vₜ) level is the reset voltage Vᵣₑₛₑₜ level or higher, both the previous state Wₜ₋₁ according to the previous input voltage (Vₜ₋₁) and the state Wₜ according to the input voltage Vₜ may be 0. For example, even when the input voltage (Vₜ) level is gradually reduced in the resistive memory element that is in the low resistance state LRS, because the input voltage (Vₜ) level is the reset voltage (Vᵣₑₛₑₜ) level or higher, the resistive memory element may be maintained in the low resistance state LRS.

That is, when the previous state Wₜ₋₁ is 0 (or the low resistance state LRS) and the input voltage (Vₜ) level is the reset voltage (Vᵣₑₛₑₜ) level or higher, the state determination module 120 may determine the previous state Wₜ₋₁ (0) as the state Wₜ (0) according to the input voltage Vₜ.

In the resistive memory element that is in the low resistance state LRS, when an applied input voltage (Vₜ) level is first lower than the reset voltage (Vᵣₑₛₑₜ) level, the previous state Wₜ₋₁ according to the previous input voltage Vₜ₋₁ may be 0, but the state Wₜ according to the input voltage Vₜ. may be determined as 1. For example, in the resistive memory element that is the low resistance state LRS, when the input voltage (Vₜ) level is gradually reduced and first becomes lower than the reset voltage (Vᵣₑₛₑₜ) level, the resistive memory element in the low resistance state LRS may be switched to the high resistance state HRS.

That is, when the previous state Wₜ₋₁ is 0 (or, the low resistance state LRS) and the input voltage (Vₜ) level is lower than the reset voltage (Vᵣₑₛₑₜ) level, the state determination module 120 may determine a state (1) different from the previous state Wₜ₋₁ (0) as the state Wₜ according to the input voltage Vₜ.

Referring to FIG. 6, the current prediction module 130 may obtain oxide layer thickness (tₒₓ) data, the input voltage (Vₜ) data (also referred to as target voltage (Vₜ) data), state (Wₜ) data according to the input voltage Vₜ. The current prediction module 130 may output current (Iₜ) data according to the input voltage Vₜ and an oxide layer thickness tₒₓ. The current prediction module 130 may also output variance (σ²_Iₜ) data for current, based on the oxide layer thickness (tₒₓ) data, the input voltage (Vₜ) data, and state (Wₜ) data according to the input voltage Vₜ.

The current prediction module 130 may generate predicted current (Iₜ) data and predicted variance (σ²_Iₜ) data for current based on the oxide layer thickness (tₒₓ) data, the input voltage (Vₜ) data, and the state (Wₜ) data according to the input voltage Vₜ.

In addition, the current prediction module 130 may include a pre-trained artificial neural network. According to an embodiment, in the offline process, the computing system 1000 may train the voltage prediction module 110, based on second labeling data, such that the current prediction module 130 predicts current Iₜ and a variance (σ²_Iₜ) corresponding thereto, based on a given oxide layer thickness tₒₓ, the input voltage Vₜ, and the state Wₜ according to the input voltage Vₜ.

Herein, the second labeling data may be a set of real current (I_{t_real}) data, which corresponds to the oxide layer thickness tₒₓ, the input voltage Vₜ, and the state Wₜ according to the input voltage Vₜ, and variance (σ²_I_{t_real}) data for a real current.

In an embodiment, in the offline process, the computing system 1000 may train the current prediction module 130 to minimize the loss of the real current (I_{t_real}) data (or the variance (σ²_I_{t_real}) for the real current and current Iₜ predicted by the current prediction module 130 (or a predicted variance (σ²_Iₜ). For example, the computing system 1000 may update parameters (e.g., weight) included in the current prediction module 130 to minimize the loss of current (I_{t_real}) data (or the variance (σ²_I_{t_real}) for the real current) and the current Iₜ predicted by the current prediction module 130 (or he predicted variance (σ²_Iₜ)).

For example, the loss of the real current I_{t_real} (or the variance (σ²_I_{t_real}) for the real current) and the predicted current Iₜ (or the predicted variance (σ²_Iₜ)) may be as shown in Equation 3:

$$\begin{matrix}L = {L}_{NLL} + {λ}_{1} {‖ {w}_{{I}_{t}} ‖}_{2}^{2} + {λ}_{2} {‖ {w}_{{σ\_ I}_{t}} ‖}_{2}^{2} \\ {L}_{NLL} = \frac{1}{2} ( log ( {σ\_I}_{t}^{2} ) ) + \frac{{( {I}_{t} - {I}_{t\_real} )}^{2}}{{σ\_I}_{t}^{2}}\end{matrix} \qquad Equation 3$$

wherein L denotes total loss, L_{NLL} denotes the loss of negative log likelihood (NLL), W_{I}_{ₜ} denotes weights for current prediction, λ₁ denotes a parameter that controls a degree of weight regularization,

$${λ}_{1} {‖ {w}_{{I}_{t}} ‖}_{2}^{2}$$

denotes an L2 norm regularization term to prevent overfitting of the weights for current prediction, W_{σ_I}_{ₜ} denotes weights for variance prediction, λ₂ denotes a parameter that controls a degree of weight regularization, and

$${λ}_{2} {‖ {w}_{{σ\_ I}_{t}} ‖}_{2}^{2}$$

denotes an N2 norm regularization term to prevent overfitting of the weights for variance prediction. Also, Iₜ denotes a predicted current, σ_Iₜ² denotes a predicted variance, and I_{t_real} denotes a real current.

In an embodiment, in the online process, the current prediction module 130 may generate current (Iₜ) data and variance (σ²_Iₜ) data for current from the obtained oxide layer thickness (tₒₓ) data, the input voltage (Vₜ) data, and the state (Wₜ) data according to the input voltage Vₜ, based on pre-trained parameters. Herein, in the offline process, the pre-trained parameters may be parameters that are updated to minimize the loss (e.g., the loss of FIG. 3) of the real current I_{t_real} (or a variance (σ²_I_{t_real}) for a real current) and the predicted current Iₜ (or the predicted variance (σ²_Iₜ)).

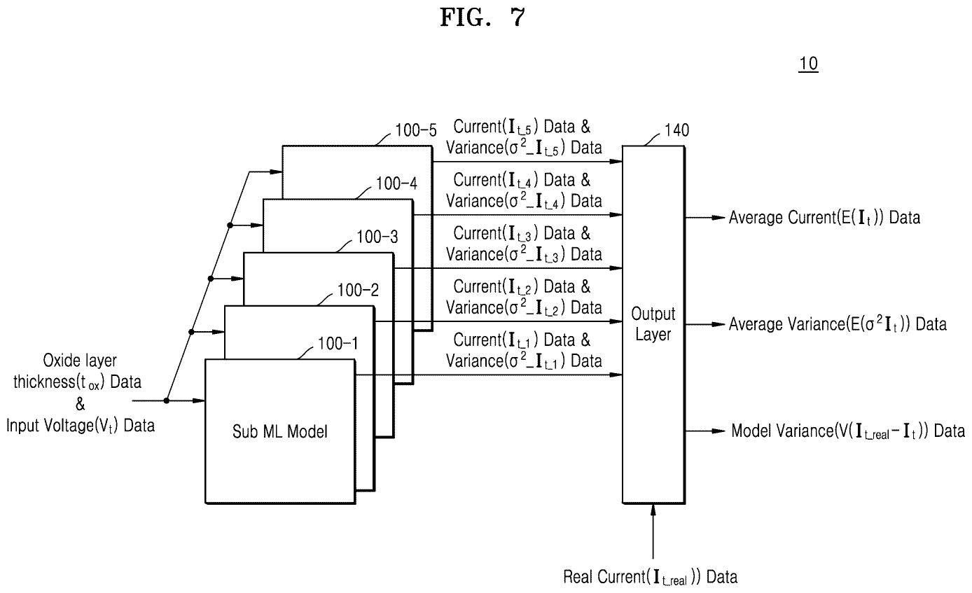

FIG. 7 is a diagram of an example of the machine learning model of FIG. 1, according to an embodiment.

Sub-ML models included in the machine learning model 10 of FIG. 1 may be implemented as first to fifth sub-ML models 100-1 to 100-5. The first to fifth sub-ML models 100-1 to 100-5 are respectively and independently trained with different random seeds, and a structure and data flow of each of the first to fifth sub-ML models 100-1 to 100-5 may correspond to those of the sub-ML model 100 of FIG. 6. Although five sub-ML models are implemented in FIG. 7, the present disclosure is not limited thereto. In some embodiments, N sub-ML models (here, N is an arbitrary positive integer) may be implemented.

That is, the machine learning model 10 may include a plurality of sub-ML models and be a model to which an ensemble method is applied. Because the first to fifth sub-ML models 100-1 to 100-5 are respectively and independently trained with different random seeds, outputs of the first to fifth sub-ML models 100-1 to 100-5 may be different in response to the same input.

Here, a random seed may be a value that controls randomness used to train sub-ML models. For example, the random seed may be an initial value of a random number generator included in a computing system 1000. The random seed may be used as an initial condition in a process of generating random numbers. When the same random number is used, the same random result may be reproduced every time.

Referring to FIG. 7, each of the first to fifth sub-ML models 100-1 to 100-5 may obtain oxide layer thickness (tₒₓ) data and input voltage (Vₜ) data (also referred to as target voltage (Vₜ) data). Each of the first to fifth sub-ML models 100-1 to 100-5 may predict current Iₜ corresponding to an input voltage Vₜ and a variance (σ²_Iₜ) for current, based on an oxide layer thickness tₒₓ. Thus, each of the first to fifth sub-ML models 100-1 to 100-5 may generate predicted current (Iₜ) data and predicted variance (σ²_Iₜ) data for current. Referring to FIG. 7, the first to fifth sub-ML models 100-1 to 100-5 may generate data about predicted currents (I_{t_1} to I_{t_5}) and predicted variance (σ²_I_{t_1} to σ²_I_{t_5}) data for respective currents.

Referring to FIG. 7, an output layer 140 may obtain, from the first to fifth sub-ML models 100-1 to 100-5, the data about the predicted currents (I_{t_1} to I_{t_5}) and the predicted variance (σ²_I_{t_1} to σ²_I_{t_5}) data for the respective currents, and output average current (E(Iₜ)) data and average variance E(σ²_Iₜ)) data.

Herein, the average current (E(Iₜ)) data may indicate an average value of the predicted currents (I_{t_1} to I_{t_5}) obtained from the first to fifth sub-ML models 100-1 to 100-5. Also, the average variance E(σ²_Iₜ)) data may indicate an average value of the predicted variances (σ²_I_{t_1} to σ²_I_{t_5}) for the respective currents, which are obtained from the first to fifth sub-ML models 100-1 to 100-5.

That is, the output layer 140 may output the average current (E(Iₜ)) data by calculating the average value of the predicted currents (I_{t_1} to I_{t_5}) obtained from the first to fifth sub-ML models 100-1 to 100-5. Also, the output layer 140 may output the average variance E(σ²_Iₜ)) data by calculating the average value of the predicted variances (σ²_I_{t_1} to σ²_I_{t_5}) for the respective currents, which are obtained from the first to fifth sub-ML models 100-1 to 100-5.

In addition, the output layer 140 may obtain real current (I_{t_real}) data. The output layer 140 may generate model variance V(I_{t_real}-Iₜ)) data about differences between a real current I_{t_real} and the predicted currents I_{t_1} to Iₜ_5, based on the real current (I_{t_real}) data and the data about the currents (I_{t_1} to I_{t_5}) predicted by the first to fifth sub-ML models 100-1 to 100-5.

That is, the output layer 140 may calculate variances for the difference between each of the currents I_{t_1} to Iₜ_5 predicted by the first to fifth sub-ML models 100-1 to 100-5 and the real current I_{t_real}, and output the model variance V(I_{t_real}-Iₜ)) data.

For example, an average current E(Iₜ))), an average variance E(σ²_Iₜ)), a model variance V(I_{t_real}-Iₜ) may be shown as in Equation 4:

$$\begin{matrix}E ( {I}_{t} ) = \frac{1}{N} {\sum }_{i = 1}^{N} {I}_{t\_i} \\ E ( {σ\_I}_{t}^{2} ) = \frac{1}{N} {\sum }_{i = 1}^{N} {σ\_I}_{t\_i}^{2} \\ V ( {I}_{{t}_{real}} - {I}_{t} ) = \frac{1}{N} {\sum }_{i = 1}^{N} {( {I}_{t\_real} - {I}_{{t}_{i}} )}^{2}\end{matrix} \qquad Equation 4$$

wherein N denotes the total number (e.g., N=5 in FIG. 7) of sub-ML models, I_{t_i} denotes current predicted by an i-th sub-ML model, σ_I_{t_i}² denotes a predicted variance for current in the i-th sub-ML model, and I_{t_real} denotes a real current.

In other words, the average variance E(σ²_Iₜ)) data may be a value that aggregates the uncertainty of intrinsic characteristics that occur in a resistive memory element, which is a prediction target. The model variance V(I_{t_real}-Iₜ) may be a numerical value of the uncertainty of the machine learning model 10, based on errors between predicted values obtained by a plurality of sub-ML models and real values.

According to the present disclosure, the accuracy and efficiency of a device simulation may be improved by segmenting and predicting both aleatoric uncertainty and epistemic uncertainty by using the machine learning model 10.

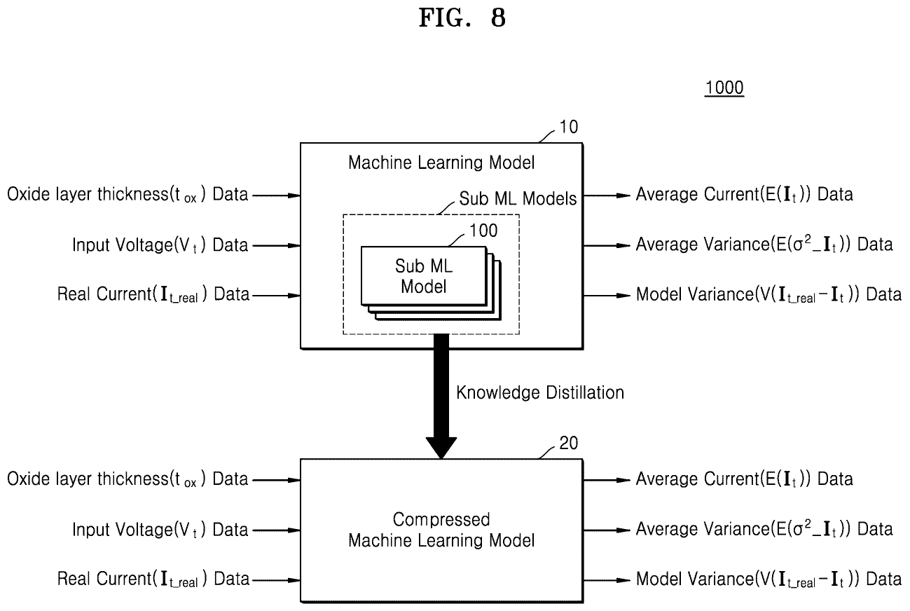

FIG. 8 is a block diagram of a computing system 1000 according to an embodiment.

The computing system 1000 of FIG. 1 may include a machine learning model 10 and/or a compressed machine learning model 20. In some embodiments, a method of performing a device simulation by using the compressed machine learning model 20 may be performed by the computing system 1000 of FIG. 8. For example, the computing system 1000 of FIG. 8 may include at least one module implemented as hardware, software, or a combination of hardware and software, and may perform the device simulation by implementing the compressed machine learning model 20 by using the at least one module. Thus, the computing system 1000 may reduce an inference runtime time (or a simulation time).

Referring to FIG. 8, the computing system 1000 may transfer knowledge of the machine learning model 10 to the compressed machine learning model 20 to reduce a size of a model while maintaining performance. That is, the computing system 1000 may create the compressed machine learning model 20 from the pre-trained machine learning model 10 by applying a knowledge distillation (KD) method. Here, the machine learning model 10 may be referred to as a teacher model, and the compressed machine learning model 20 may be referred to as a student model.

That is, the computing system 1000 may create the compressed machine learning model 20 by training a machine learning model different from the machine learning model 10, based on output data (e.g., third labeling data to be described below) of the machine learning model 10. Here, the compressed machine learning model 20 (or a machine learning model different from the machine learning model 10) may include a single artificial neural network.

According to an embodiment, in an offline process, the computing system 1000 may train the compressed machine learning model 20, based on the third labeling data, such that the compressed machine learning model 20 predicts an average current E(Iₜ) and an average variance E(σ²_Iₜ) corresponding thereto, based on a given oxide layer thickness tₒₓ and an input voltage Vₜ. In the offline process, the computing system 1000 may train the compressed machine learning model 20, based on the third labeling data, such that the compressed machine learning model 20 predicts the corresponding model variance V(I_{t_real}-Iₜ), based on a given real current I_{t_real}.

Herein, the third labeling data may include the average current E(Iₜ) and the average variance E(σ²_Iₜ) that are the corresponding output values of the machine learning model 10, based on the given oxide layer thickness tₒₓ and the input voltage Vₜ. Also, the third labeling data may include the model variance V(I_{t_real}-Iₜ) that is a corresponding output value of the machine learning model 10, based on the given real current I_{t_real}. That is, the third labeling data may include the output values of the machine learning model 10 for given input values.

In an embodiment, in an online process, the compressed machine learning model 20 may generate current (Iₜ) data and variance (σ²_Iₜ) data for current from obtained oxide layer thickness (tₒₓ) data and input voltage (Vₜ) data, based on pre-trained parameters. In the online process, the compressed machine learning model 20 may generate model variance V(I_{t_real}-Iₜ)) data from real current (I_{t_real}) data, based on the pre-trained parameters. Herein, in the offline process, the pre-trained parameters may be parameters that are updated, based on the third labeling data, to the loss of the output value of the machine learning model 10 and an output value of the compressed machine learning model 20.

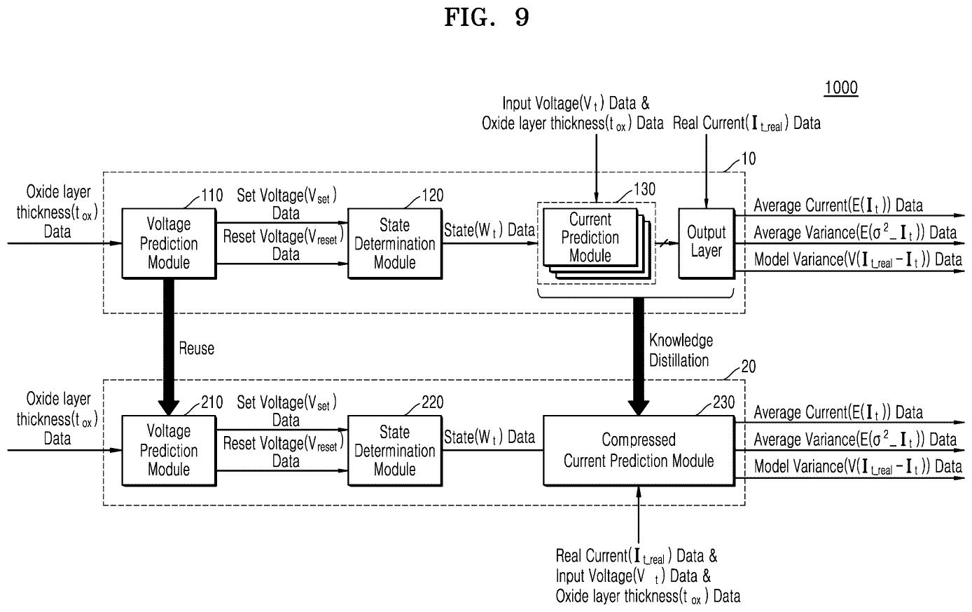

FIG. 9 is a diagram illustrating an example of a KD method of the computing system 1000 of FIG. 8.

FIG. 9 illustrates a machine learning model 10 including sub-ML models described with reference to FIGS. 6 and 7 and a compressed machine learning model 20 to which knowledge is to be transferred. Referring to FIG. 9, it can be seen that an ensemble method has been applied to a current prediction module 130 of the machine learning model 10.

Referring to FIG. 9, the compressed machine learning model 20 may include a voltage prediction module 210, a state determination module 220, and a compressed current prediction module 230. Structures and data flows of the voltage prediction module 210, the state determination module 220, and the compressed current prediction module 230 may respectively correspond to the voltage prediction module 110, the state determination module 120, and the current prediction module 130 of FIG. 6. Hereinafter, redundant descriptions are omitted, and only differences are described.

The computing system 1000 may reuse the voltage prediction module 110 of the machine learning model 10 as the voltage prediction module 210 of the compressed machine learning model 20. That is, because the voltage prediction module 110 has a smaller computational amount than the current prediction module 130 to which the ensemble method is applied, the computing system 1000 may reuse the voltage prediction module 210 of the machine learning model 10 as the voltage prediction module 110 of the compressed machine learning model 20.

In an embodiment, in an offline process, the computing system 1000 may not additionally train the voltage prediction module 110 of the compressed machine learning model 20. In an online process, the voltage prediction module 210 may reuse pre-trained parameters of the voltage prediction module 110, and thus, the voltage prediction module 210 may generate set voltage (Vₛₑₜ) data and reset voltage (Vᵣₑₛₑₜ) data from obtained oxide layer thickness (tₒₓ) data.

The computing system 1000 may train the compressed current prediction module 230 by applying a KD method to an output layer 140 and the current prediction module 130 to which the ensemble method is applied in the machine learning model 10.

In the offline process, the computing system 1000 may train the compressed current prediction module 230, based on the third labeling data described with reference to FIG. 8, such that the compressed current prediction module 230 predicts an average current E(Iₜ) and an average variance E(σ²_Iₜ) corresponding thereto, based on a given oxide layer thickness tₒₓ, a state Wₜ, and an input voltage Vₜ (also referred to as target voltage (Vₜ) data). In the offline process, the computing system 1000 may train the compressed current prediction module 230, based on the third labeling data described with reference to FIG. 8, such that the compressed current prediction module 230 predicts a corresponding model variance V(I_{t_real}-Iₜ), based on a given real current I_{t_real}.

In an embodiment, in the online process, the compressed current prediction module 230 may generate current (Iₜ) data and variance (σ²_Iₜ) data for current from the obtained oxide layer thickness (tₒₓ) data, state (Wₜ) data, and input voltage (Vₜ) data, based on the pre-trained parameters. In the online process, the compressed current prediction module 230 may generate model variance V(I_{t_real}-Iₜ)) data from real current (I_{t_real}) data, based on the pre-trained parameters. Herein, in the offline process, the pre-trained parameters may be parameters that are updated based on the third labeling data described with reference to FIG. 8, to minimize the loss of an output value of the machine learning model 10 and an output value of the compressed machine learning model 20.

According to the present disclosure, knowledge of the current prediction module 130 to which the ensemble method is applied may be transferred to the compressed current prediction module 230 by using a KD method, and thus, the entire model structure may be made lighter. Thus, the computing system 1000 may reduce an inference runtime time (or a simulation time).

In some embodiments, to further reduce the inference runtime time (or the simulation time), a pruning-retaining method may be additionally applied to the compressed current prediction module 230.

The computing system 1000 may remove relatively small weights from an artificial neural network that implements the compressed current prediction module 230, and thus, a pruning method of reducing the number of parameters of the compressed current prediction module 230 may be applied to the compressed current prediction module 230. Subsequently, the comput7ing system 1000 may retain the compressed current prediction module 230 to which the pruning method is applied, by using the third labeling data described above.

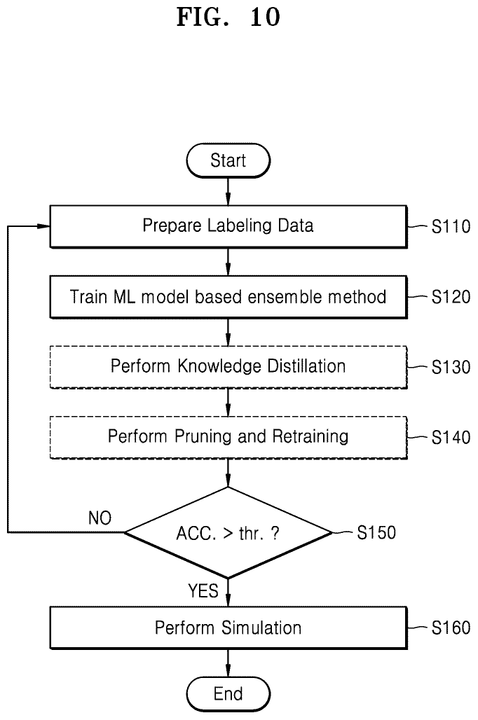

FIG. 10 is a flowchart of an example of an operation of a computing system according to an embodiment.

A method of performing a device simulation by using the machine learning model 10 and/or the compressed machine learning model 20 described above is described with reference to FIG. 10. However, as used herein, the properties of a semiconductor device formed using a semiconductor process will be described as examples, but embodiments are not limited thereto.

Referring to FIG. 10, in operation S110, a computing system 1000 may prepare labeling data. For example, the labeling data may include experimental data and simulation data generated by the compact model according to Equation 1. Also, the labeling data may include the first labeling data and the second labeling data described above.

That is, the computing system 1000 may obtain the labeling data as training data for training the machine learning model 10.

Referring to FIG. 10, in operation S120, the computing system 1000 may train the machine learning model 10 based on an ensemble method. A detailed description of operation S120 is replaced by the description of FIGS. 1 to 7.

Referring to FIG. 10, operations S130 and S140 may be performed in some embodiments. In operation S130, the computing system 1000 may train the compressed machine learning model 20 from the machine learning model 10 by using a KD method. Herein, the computing system 1000 may train the compressed machine learning model 20 by using the third labeling data described above. In operation S140, the computing system 1000 may prune and retrain the compressed machine learning model 20. A detailed description of operations S130 and S140 is replaced by the description of FIGS. 8 and 9.

Referring to FIG. 10, in operation S140, the computing system 1000 may determine whether a prediction accuracy of the machine learning model 10 or the compressed machine learning model 20 exceeds a predefined threshold value. Here, the prediction accuracy may be a predicted variance (σ²_Iₜ) for current or a model variance V(I_{t_real}-Iₜ)) for a difference between a real current I_{t_real} and a predicted current Iₜ.

When operations S130 and S140 are performed, in operation S150, the computing system 1000 may determine whether the prediction accuracy of the compressed machine learning model 20 exceeds the predefined threshold value.

In some embodiments, when operations S130 and S140 are not performed, in operation S150, the computing system 1000 may determine whether the prediction accuracy of the machine learning model 10 exceeds the predefined threshold value.

In operation S150, it may be determined that the prediction accuracy of the machine learning model 10 or the compressed machine learning model 20 does not exceed the predefined threshold value, and the computing system 1000 may return to operation S110, based on the determination result. In operation S110, the computing system 1000 may additionally obtain the labeling data such that the prediction accuracy of the machine learning model 10 or the compressed machine learning model 20 exceeds the predefined threshold value. Operations S110 to S150 or a series of operations S110, S120, and S150 may be repeated until the prediction accuracy of the machine learning model 10 or the compressed machine learning model 20 exceeds the predefined threshold value.

In operation S150, it may be determined that the prediction accuracy of the machine learning model 10 or the compressed machine learning model 20 exceeds the predefined threshold value, and the computing system 1000 may proceed to operation S160, based on the determination result.

In operation S160, the computing system 1000 may perform a circuit simulation by using the machine learning model 10 or the compressed machine learning model 20. For example, the circuit simulation may be a SPICE simulation.

That is, the computing system 1000 may predict current, a voltage, and a state of the semiconductor device by using the machine learning model 10 or the compressed machine learning model 20 and use the predicted current, voltage, and state for the SPICE simulation. According to the present disclosure, the performance of a device simulation may be improved by approximating physical operations of the semiconductor device (e.g., the above-described ReRAM) by using a machine learning-based compact model (e.g., the machine learning model 10 or the compressed machine learning model 20). According to the present disclosure, design optimization may be achieved by integrating the machine learning-based compact model (e.g., the machine learning model 10 or the compressed machine learning model 20) with the SPICE simulation.

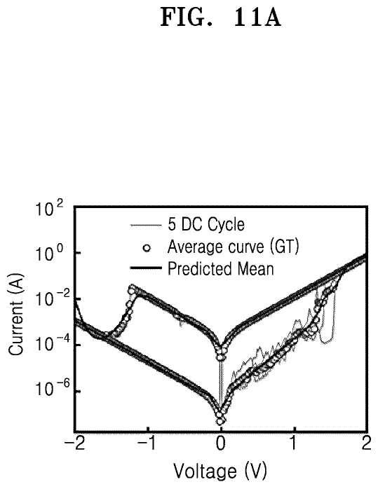

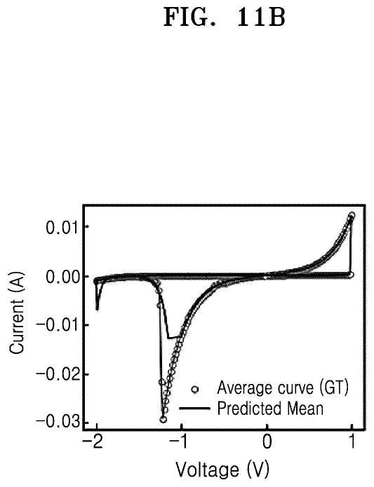

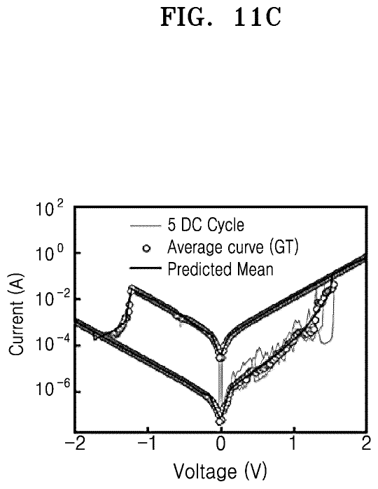

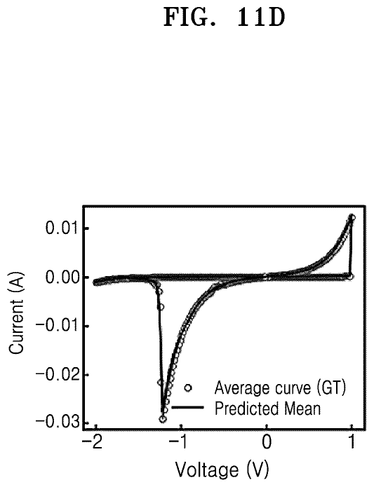

FIGS. 11A and 11B are graphs showing a predicted current corresponding to an input voltage of a machine learning model according to a comparative example, and FIGS. 11C and 11D are graphs showing a predicted current corresponding to an input voltage of a machine learning model according to an embodiment. FIGS. 11A and 11B are graphs to which a logarithmic scale is applied, and FIGS. 11B and 11D are graphs to which a linear scale is applied.

The machine learning model 10 (or the compressed machine learning model 20) according to the present disclosure may include the state determination module 120 (or the state determination module 220), while the machine learning model according to the comparative example may not include the state determination module 120 (or the state determination module 220).

Referring FIGS. 11A and 11B, because the machine learning model according to the comparative example does not include the state determination module 120 (or the state determination module 220), it can be seen that the prediction accuracies of switching voltages (e.g., a set voltage Vₛₑₜ and a reset voltage Vᵣₑₛₑₜ) are reduced.

In contrast, referring to FIGS. 11C and 11D, because the machine learning model (or the compressed machine learning model 20) according to the present disclosure includes the state determination module 120 (or the state determination module 220), it can be seen that the prediction accuracies of switching voltages (e.g., a set voltage Vₛₑₜ and a reset voltage Vᵣₑₛₑₜ) are high.

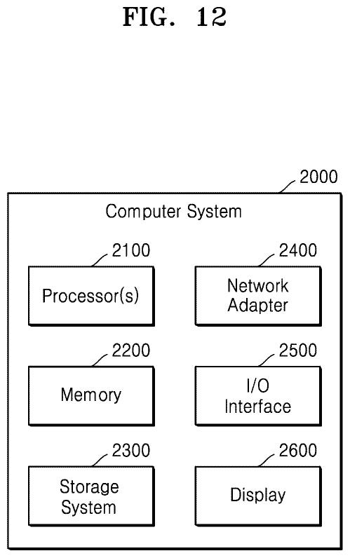

FIG. 12 is a block diagram of a computer system 2000 according to an embodiment.

In some embodiments, the computer system 2000 of FIG. 12 may train the machine learning models described above with reference to the drawings and may be referred to as a semiconductor simulator system or a training system.

The computer system 2000 may refer to any system including a general-use or exclusive-use computing system. For example, the computer system 2000 may include personal computers, server computers, laptop computers, home appliances, etc. As shown in FIG. 12, the computer system 2000 may include at least one processor 2100, a memory 2200, a storage system 2300, a network adaptor 2400, an input/output (I/O) interface 2500, and a display 2600.

The at least one processor 2100 may execute a program module including instructions that may be executed by a computer system. The program module may include routines, programs, objects, components, logics, data structures, etc., which perform specific tasks or implement specific abstract data types. The memory 2200 may include a computer system readable medium of the type of a volatile memory, such as RAM. The at least one processor 2100 may provide access to the memory 2200 and execute instructions loaded in the memory 2200. The storage system 2300 may store information in a non-volatile manner. In some embodiments, the storage system 2300 may include at least one program product including a program module configured to train machine learning models described above with reference to the drawings. The programs may include, but are not limited thereto, an operating system, at least one application, other program modules, and program data.

The network adaptor 2400 may provide access to a local area network (LAN), a wide area network (WAN) and/or a public network (e.g., the Internet). The I/O interface 2500 may provide a communication channel with peripheral devices, such as a keyboard, a pointing device, an audio system, and the like. The display 2600 may output a variety of information for a user to check.

In some embodiments, the training of the machine learning models described above with reference to the drawings may be implemented by a computer program product. The computer program product may include a non-transitory computer-readable medium (or a storage medium) including computer-readable program instructions for causing the at least one processor 2100 to process images and/or train models. Computer-readable program instructions may be, but are not limited thereto, assembler instructions, instruction set architecture (ISA) instructions, machine instructions, machine-dependent instructions, microcode, firmware instructions, state setting data, or source code or object code written in at least one programming language.

A computer-readable medium may be any type of medium capable of non-transitorily instructions that are executed by the at least one processor 2100 or any device capable of executing instructions. The computer-readable medium may be, but is not limited thereto, an electronic storage device, a magnetic storage device, an optical storage device, an electromagnetic storage device, a semiconductor storage device, or any combination thereof. For example, the computer-readable medium may be a mechanically encoded device, such as a portable computer diskette, a hard disk, RAM, read-only memory (ROM), electrically erasable read only memory (EEPROM), flash memory, static RAM (SRAM), compact disk (CD), digital versatile disc (DVD), a memory stick, a floppy disk, and a punch card, or any combination thereof.

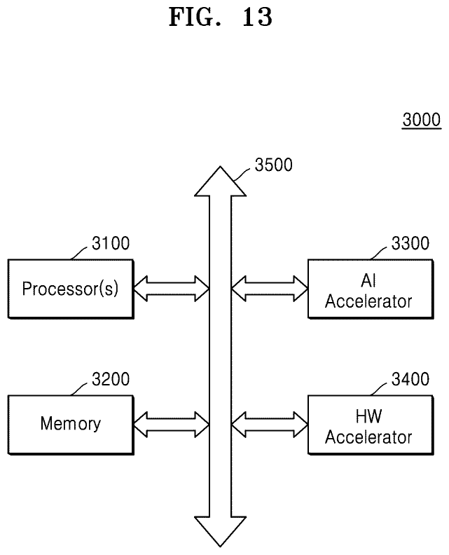

FIG. 13 is a block diagram of a system according to an embodiment.

In some embodiments, a machine learning model according to an embodiment may be executed by a system 3000. Accordingly, the system 3000 may have a low complexity and rapidly generate accurate results.

Referring to FIG. 13, the system 3000 may include at least one processor 3100, a memory 3200, an artificial intelligence (AI) accelerator 3300, and a hardware accelerator (or HW accelerator) 3400. The at least one processor 3100, the memory 3200, the AI accelerator 3300, and the hardware accelerator 3400 may communicate with each other via a bus 3500. In some embodiments, the at least one processor 3100, the memory 3200, the AI accelerator 3300, and the hardware accelerator 3400 may be included in a single semiconductor chip. In some embodiments, at least two of the at least one processor 3100, the memory 3200, the AI accelerator 3300, and the hardware accelerator 3400 may be respectively included in at least two semiconductor chips mounted on a board.

The at least one processor 3100 may execute instructions. For example, by executing instructions stored in the memory 3200, the at least one processor 3100 may execute an operating system or execute applications running on the operating system. In some embodiments, by executing the instructions, the at least one processor 3100 may instruct the AI accelerator 3300 and/or the hardware accelerator 3400 to perform tasks, and may obtain the results of the tasks from the AI accelerator 3300 and/or the hardware accelerator 3400. In some embodiments, the at least one processor 3100 may be an Application Specific Instruction set Processor (ASIP) customized for a specific purpose and support a dedicated instruction set.

The memory 3200 may have an arbitrary structure configured to store data. For example, the memory 3200 may include a volatile memory device, such as dynamic RAM (DRAM) and static RAM (SRAM), or include a non-volatile memory device, such as flash memory and RRAM. The at least one processor 3100, the AI accelerator 3300, and the hardware accelerator 3400 may store data (e.g., IN, IMG_I, IMG_O, and OUT of FIG. 2) in the memory 3200 through the bus 3500 or read data (e.g., IN, IMG_I, IMG_O, and OUT of FIG. 2) from the memory device 3200.

The AI accelerator 3300 may refer to hardware designed for AI applications. In some embodiments, the AI accelerator 3300 may include a neural processing unit (NPU) configured to implement a neuromorphic structure. The AI accelerator 3300 may generate output data by processing input data provided by the at least one processor 3100 and/or the hardware accelerator 3400, and may provide the output data to the at least one processor 310 and/or the hardware accelerator 3400. In some embodiments, the AI accelerator 3300 may be programmable and be programmed by the at least one processor 3100 and/or the hardware accelerator 3400.

The hardware accelerator 3400 may refer to hardware designed to perform specific tasks at high speed. For example, the hardware accelerator 3400 may be designed to perform data conversion (e.g., demodulation, modulation, encoding, and decoding) at high speed. The hardware accelerator 3400 may be programmable and be programmed by the at least one processor 3100 and/or the hardware accelerator 3400.

In some embodiments, the AI accelerator 3300 may execute machine learning models described above with reference to the drawings. For example, the AI accelerator 3300 may execute each of the above-described layers. The AI accelerator 3300 may generate outputs including useful information by processing input parameters, feature maps, etc. In some embodiments, at least some of models executed by the AI accelerator 3300 may be executed by the at least one processor 3100 and/or the hardware accelerator 3400.

While the present disclosure has been particularly shown and described with reference to embodiments thereof, it will be understood that various changes in form and details may be made therein without departing from the spirit and scope of the following claims.

What is claimed is:

1. A method of performing a device simulation of a resistive memory element, the method being executed by at least one processor, the method comprising:
obtaining oxide layer thickness data and input voltage data of the resistive memory element;
generating predicted current data and predicted variance data for a current based on a machine learning model, wherein the generating the predicted current data and the predicted variance data comprises predicting a current corresponding to an input voltage;
generating model variance data associated with a difference between a real current and the predicted current, based on the machine learning model; and
performing a circuit simulation based on the machine learning model, the predicted variance data, and the model variance data.

2. The method of claim 1, wherein the machine learning model comprises a plurality of sub-machine learning models and an output layer,
wherein the generating the predicted current data and the predicted variance data for the current comprises:
obtaining, by each of the plurality of sub-machine learning models, the oxide layer thickness data and the input voltage data; and
obtaining, by the output layer, respective predicted current data and respective predicted variance data for data from the plurality of sub-machine learning models and outputting average current data and average variance data.

3. The method of claim 1, wherein the machine learning model comprises voltage prediction layers, state determination layers, and current prediction layers,
wherein the method further comprises:
generating, by the voltage prediction layers, predicted set voltage data and predicted reset voltage data by predicting a set voltage and a reset voltage of the resistive memory element, corresponding to oxide layer thickness data;
generating, by the state determination layers, state data according to the input voltage, based on the input voltage data, the predicted set voltage data, the predicted reset voltage data, and previous state data; and
generating, by the current prediction layers, the predicted current data and the predicted variance data for the current by predicting the current of the resistive memory element, based on the oxide layer thickness data, the input voltage data, and the state data according to the input voltage.

4. The method of claim 3, wherein the generating, by the state determination layers, the state data comprises:
comparing, by the state determination layers, the input voltage with the set voltage and the reset voltage; and
determining a previous state as a state according to the input voltage or determining a state different from the previous state as the state according to the input voltage, based on whether specific conditions are satisfied.

5. The method of claim 3, wherein the generating of, by the state determination layers, the state data comprises determining, by the state determination layers, a previous state as a state according to the input voltage based on the previous state being a high resistance state and an input voltage level being lower than a set voltage level.

6. The method of claim 3, wherein the generating of, by the state determination layers, the state data comprises determining, by the state determination layers, a state different from a previous state as a state according to the input voltage based on the previous state being a high resistance state and an input voltage level being a set voltage level or higher.

7. The method of claim 3, wherein the generating, by the state determination layers, the state data comprises determining, by the state determination layers, a previous state as a state according to the input voltage based on the previous state being a low resistance state and an input voltage level being a reset voltage level or higher.

8. The method of claim 3, wherein the generating of, by the state determination layers, the state data comprises determining, by the state determination layers, a state different from a previous state as a state according to the input voltage based on the previous state being a low resistance state and an input voltage level being lower than a reset voltage level.

9. The method of claim 1, further comprising creating a compressed machine learning model based on the machine learning model, by training a second machine learning model using output data of the machine learning model.

10. The method of claim 9, wherein the creating of the compressed machine learning model comprises:
applying a pruning method for reducing a number of parameters of the compressed machine learning model; and
retraining a compressed current prediction module to which the pruning method is applied, based on the output data of the machine learning model.

11. A non-transitory computer-readable storage medium comprising instructions, wherein, when the instructions are executed by at least one processor, the instructions cause the at least one processor to:
obtain oxide layer thickness data and input voltage data of a resistive memory element;
generate predicted current data and predicted variance data for a current based on a machine learning model, wherein the generating the predicted current data and the predicted variance data comprises predicting a current corresponding to an input voltage;
generate model variance data associated with a difference between a real current and the predicted current, based on the machine learning model; and
perform a circuit simulation based on the machine learning model, the predicted variance data, and the model variance data.

12. A computing system comprising at least one processor, the at least one processor being configured to:
obtain oxide layer thickness data and input voltage data of a resistive memory element;
generate predicted current data and predicted variance data for a current based on a machine learning model, wherein the generating the predicted current data and the predicted variance data comprises predicting a current corresponding to an input voltage;
generate model variance data associated with a difference between a real current and the predicted current, based on the machine learning model; and
perform a circuit simulation based on the machine learning model, the predicted variance data, and the model variance data.

13. The computing system of claim 12, wherein the machine learning model comprises a plurality of sub-machine learning models and an output layer,
wherein each of the plurality of sub-machine learning models is configured to obtain the oxide layer thickness data and the input voltage data, and
wherein the output layer is configured to obtain respective predicted current data and respective predicted variance data for the current from each of the plurality of sub-machine learning models and output average current data and average variance data.

14. The computing system of claim 12, wherein the machine learning model comprises voltage prediction layers, state determination layers, and current prediction layers,
the voltage prediction layers are configured to generate predicted set voltage data and predicted reset voltage data by predicting a set voltage and a reset voltage of the resistive memory element, corresponding to the oxide layer thickness data,
the state determination layers are configured to generate state data according to the input voltage, based on the input voltage data, the predicted set voltage data, the predicted reset voltage data, and previous state data, and
the current prediction layers are configured to generate the predicted current data and the predicted variance data for the current by predicting the current of the resistive memory element, based on the oxide layer thickness data, the input voltage data, and the state data according to the input voltage.

15. The computing system of claim 14, wherein the state determination layers are configured to:
compare the input voltage with the set voltage and the reset voltage; and
determine a previous state as a state according to the input voltage or determine a state different from the previous state as the state according to the input voltage, based on whether specific conditions are satisfied.

16. The computing system of claim 14, wherein the state determination layers are configured to determine a previous state as a state according to the input voltage when the previous state is a high resistance state and an input voltage level is lower than a set voltage level.

17. The computing system of claim 14, wherein the state determination layers are configured to determine a state different from a previous state as a state according to the input voltage when the previous state is a high resistance state and an input voltage level is a set voltage level or higher.

18. The computing system of claim 14, wherein the state determination layers are configured to determine a previous state as a state according to the input voltage when the previous state is a low resistance state and an input voltage level is a reset voltage level or higher.

19. The computing system of claim 14, wherein the state determination layers are configured to determine a previous state different from the previous state as a state according to the input voltage when the previous state is a low resistance state and an input voltage level is lower than a reset voltage level.

20. The computing system of claim 12, wherein the at least one processor creates a compressed machine model based on the machine learning model, by training a second machine learning model using output data of the machine learning model.
